(19) United States
(12) Patent Application Publication
(10) Pub. No.: US 2005/0018235 A1
(43) Pub. Date: Jan. 27, 2005

(54) Printer utility program, print system, and printer monitoring method

(75) Inventor: Yukiko Shikata, Nagano (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/877,765

(22) Filed: Jun. 24, 2004

(30) Foreign Application Priority Data
Jun. 27, 2003 (JP) P.2003-184430

(51) Int. Cl. G06F 15/00; G03F 3/08

(52) U.S. Cl. 358/1.14

(57) ABSTRACT

The present invention aims too provide a printer utility program for causing a computer to display information concerning a handling method of an abnormal phenomenon occurring in a printer, that can be created as a small amount of information to notify the user of a handling method is only provided. In the present invention, the printer utility program is created so that it can cause a computer to perform processing of displaying a combination of messages specifying whether or not display is required according to ON/OFF of each bit of information transmitted by a printer to notify the user of an abnormal phenomenon occurring in the printer as information concerning a handling method of the abnormal phenomenon.

### BACKGROUND OF THE INVENTION

1. Field of the Invention

This invention relates to a printer utility program and a print system. It also relates to a printer monitoring method.

2. Description of the Related Art

As known, most printers commercially available at present can display information concerning the type of abnormal phenomenon occurring in the printer and a handling method (elimination procedure) of the abnormal phenomenon on a display of a computer using the printer.

Specifically, a printer 130 that can display information concerning the description (type) of abnormal phenomenon occurring in the printer and a handling method of the abnormal phenomenon on a display of a computer 150 as the printer is used in a manner shown in FIG. 5 is commercially available. (For example, refer to non-patent document 1: “AcuLaser C4000 Reference Guide,” SEIKO Epson Corporation, 2001.)

The printer 130 is an apparatus having a status information return function of returning status information representing the state of the home apparatus at the point in time upon reception of a status information request of a predetermined description. The printer 130 is also an apparatus including three points where a paper jam can occur, and returns status information containing an error code indicating occurrence of a paper jam and jam occurrence part information (information that can take any of seven values) indicating the n (n=any of 1 to 3) points where there is a possibility that a paper jam may occur upon reception of a status information request in a state in which a paper jam occurs.

On the other hand, a printer driver 120 installed in a computer 150 using the printer 130 is a program for causing the computer 150 to perform processing of generating print data for the printer 130 and transmitting the print data to the printer 130.

A monitor program 110 is a program for causing the computer 150 to perform processing of acquiring status information from the printer 130 periodically, thereby monitoring the operation state of the printer 130 and if an abnormal phenomenon occurs in the printer 130, displaying an error notification window indicating the type of abnormal phenomenon and a handling method of the abnormal phenomenon, such as an error notification window shown in FIG. 6, on a display. The monitor program 110 can also be made resident; however, usually it is a program used in such a manner that it is started by the printer driver 120.

The error notification window shown in FIG. 6 is displayed when a paper jam occurs in the printer 130. The monitor program 110 creates and displays this kind of error notification window by building handling method description information (“Open cover A or B, and remove the paper cassette. Remove any jammed paper.” in FIG. 6) provided for each of the values of the jam occurrence part information in a model of error notification window.

That is, the monitor program 110 is a program for which seven pieces of handling method description information must be provided for seven types of paper jams to create the program and also contains the handling method description information and therefore the created monitor program must result in a comparatively large size.

### SUMMARY OF THE INVENTION

It is therefore an object of the invention to provide a printer utility program for causing a computer to display information concerning a handling method of an abnormal phenomenon occurring in a printer, the printer utility program that can be created as a small amount of information to notify the user of a handling method is only provided.

It is another object of the invention to provide a print system that can cause a host to display information concerning a handling method of an abnormal phenomenon occurring in a printer, the print system that can be constructed as a small amount of information to notify the user of a handling method (abnormal phenomenon elimination procedure) is only provided.

To the ends, according to the invention, there is provided a printer utility program for causing a computer to operate as an apparatus including information storage means storing different types of pieces of character string information; and information display means for determining an abnormal phenomenon occurring in a printer and displaying information provided by combining as many different types of pieces of character string information as the number of pieces of character string information responsive to the determined abnormal phenomenon, stored in the information storage means as information concerning a handling method of the abnormal phenomenon occurring in the printer.

That is, the printer utility program of the invention can cause a computer to perform processing of displaying a combination of several pieces of character string information as information concerning a handling method of one abnormal phenomenon occurring in a printer. Therefore, according to the invention, as a program having a similar function concerning paper jams to that of the monitor program 110 can be created if three types of pieces of character string information are provided, the printer utility program that can cause a computer to display information concerning a handling method of an abnormal phenomenon occurring in a printer can be created simply by providing a smaller amount of information than the program in the related art for which handling method description information must be provided for each abnormal phenomenon.

To implement the printer utility program of the invention, an apparatus that can transmit display description specification information specifying one or more pieces of character string information stored in the information storage means to a different apparatus can be adopted as the printer, and the information display means can be means for displaying information provided by combining one or more pieces of character string information stored in the information storage means and specified by the display description specification information transmitted by the printer.

The printer utility program of the invention may be implemented as the information display means is means for displaying information provided by combining one or more pieces of character string information stored in the information storage means and specified by the display description specification information transmitted by the printer and displaying an image provided by combining one or more images provided in a one-to-one correspondence with the one or more pieces of character string information. Further, the printer utility program of the invention may cause the computer to operate as the apparatus further including monitor means for monitoring occurrence of an abnormal phenomenon in the printer, wherein the information display means functions when the monitor means detects occurrence of an abnormal phenomenon.

According to the invention, there is provided a print system including a host equivalent to a computer installing the printer utility program as claimed in claim 2 and a printer including state information transmission means for transmitting status information containing as many different types of pieces of character string specification information as the number of pieces of character string information responsive to the type of abnormal phenomenon occurring in the printer to a different apparatus. Thus, the print system functions as a system that can cause the host to display information concerning an abnormal phenomenon occurring in the printer and can be constructed as a small amount of information to notify the user of the handling method is only provided.

### BRIEF DESCRIPTION OF THE DRAWINGS

FIG. 1 is a drawing to show the configuration of a print system according to one embodiment of the invention;

FIG. 2 is a schematic representation of paper jam definition information contained in a printer utility program according to the embodiment of the invention;

FIG. 3 is a flowchart of paper jam occurrence notification processing executed by a computer according to the printer utility program;

FIG. 4 is a schematic representation of a paper jam error notification window displayed by performing the paper jam occurrence notification processing;

FIG. 5 is a drawing to show the configuration of a print system in a related art; and

FIG. 6 is a schematic representation of a paper jam error notification window displayed on a computer contained in the print system in the related art.

In the drawings, a reference numeral 10 refers to a printer utility program; 20 to a printer driver; and 30 to a printer; 50 to a computer.

### DETAILED DESCRIPTION OF THE PREFERRED EMBODIMENTS

Referring now to the accompanying drawings, there is shown a preferred embodiment of the invention.

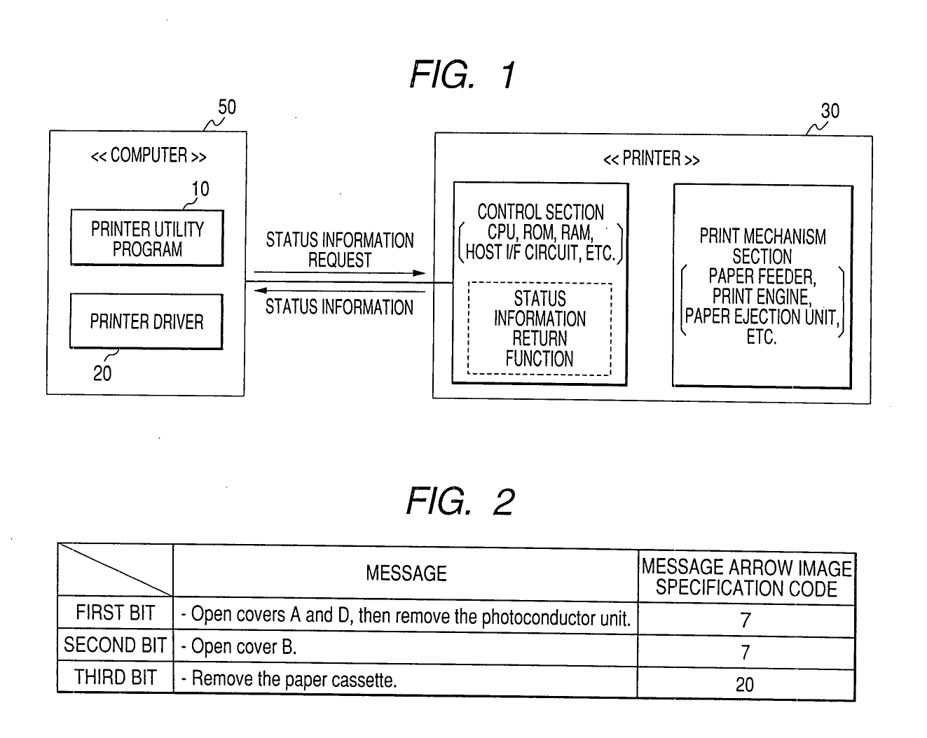

To begin with, a print system according to one embodiment of the invention is outlined with FIG. 1.

As shown in the figure, the print system according to the embodiment is a system including a printer 30 and a computer 50 installing a printer utility program 10 and a printer driver 20.

The printer 30 forming a part of the print system requires that the user conduct any one or more of three types of paper jam elimination work to eliminate a paper jam state like the printer 130 in the related art described above. The printer 30 also has a status information return function (a function of returning status information upon reception of a status information request) like the printer 130. However, the status information return function of the printer 30 is to return status information containing an error code indicating occurrence of a paper jam (paper jam error code) and display description specification information (in the embodiment, one-byte information) with the value of the first to third bits indicating whether or not the user should conduct specific paper jam elimination work when a paper jam occurs.

The printer driver 20 installed in the computer 50 forming a part of the print system is a driver program for the printer 30.

The printer utility program 10 is a program that can cause the computer 50 to perform processing almost similar to the processing of the monitor program 110 in the related art described above. However, the processing executed by the computer 50 according to the printer utility program 10 is processing of displaying a paper jam error notification window (an error notification window for notifying the user of occurrence of a paper jam, etc.,) according to a different procedure from the processing executed by the computer 150 according to the monitor program 110.

On the understanding of the description given above, the configuration and the operation of the print system according to the embodiment will be discussed furthermore specifically.

The printer utility program 10 according to the embodiment is a program (a set of EXE files, DLL files, etc.,) containing paper jam definition information and various arrow images (image data representing arrows).

The paper jam definition information contained in the printer utility program 10 is information used to display the paper jam error notification window. The paper jam definition information is information containing a message and an arrow image specification code for each of the first to third bits of the display description specification information, as schematically shown in FIG. 2. A specific use method of the paper jam definition information is described later. Each arrow image specification code contained in the paper jam definition information is information specifying that the corresponding arrow image contained in the printer utility program 10 should be displayed on the paper jam error notification window. Each arrow image specification code not contained in the paper jam definition information (1, 2, etc.,) is information specifying that the corresponding arrow image contained in the printer utility program 10 should be displayed on any other error notification window than the paper jam error notification window.

The processing executed by the computer 50 according to the printer utility program 10 is processing using the paper jam definition information to display the paper jam error notification window.

Specifically, the computer 50 starting processing responsive to the printer utility program 10 enters a state (usual state) in which it acquires status information from the printer 30 periodically, thereby monitoring change in the operation state of the printer 30 (between occurrence of an abnormal phenomenon such as a paper jam in the printer 30 and restoration of the printer 30 to the normal state).

Upon detection of occurrence of a paper jam in the printer 30 (upon reception of status information containing a paper jam error code and display description specification information), the computer 50 starts paper jam occurrence notification processing, processing to display the paper jam error notification window on the display.

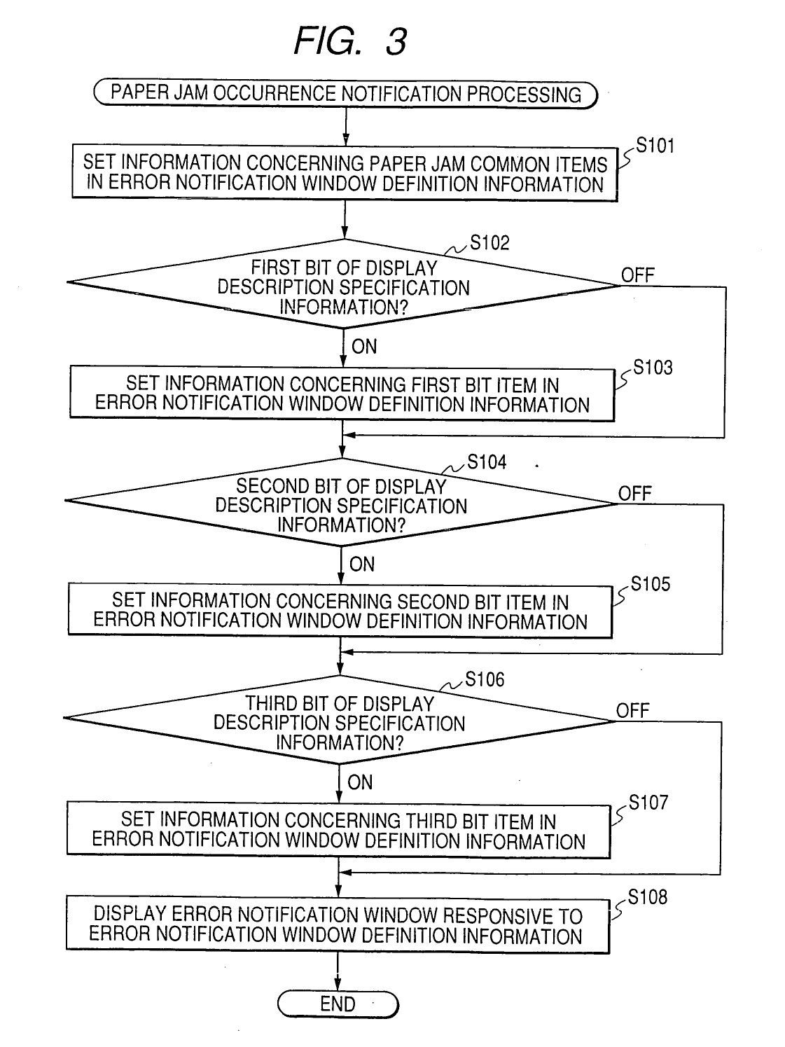

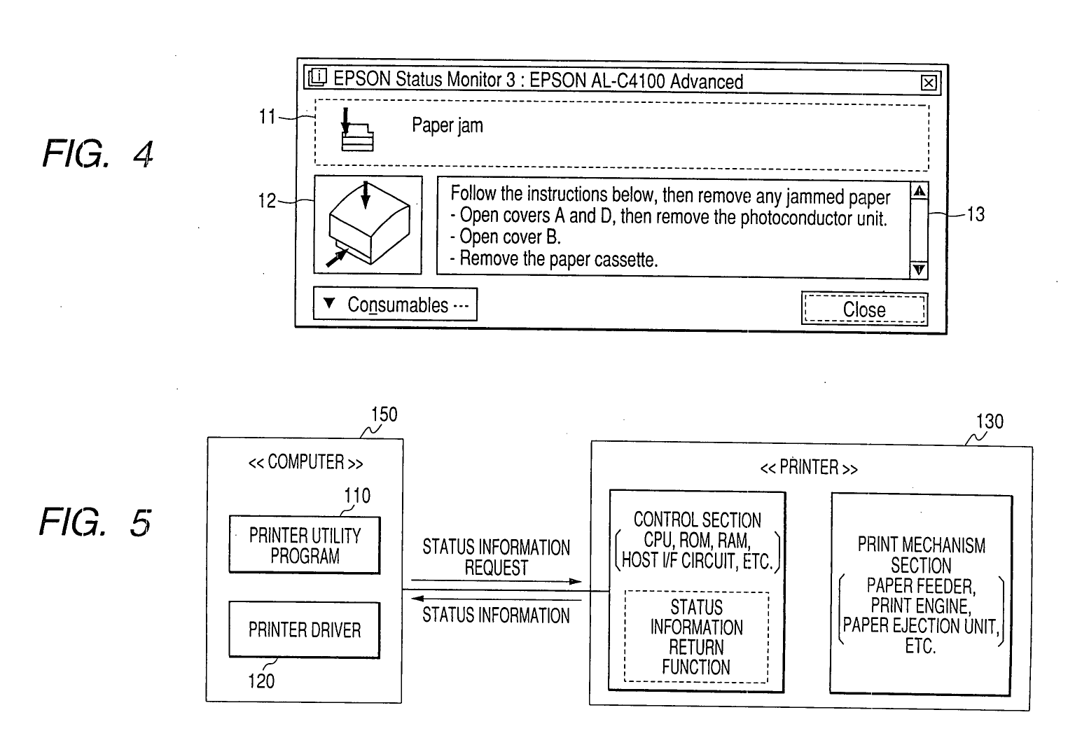

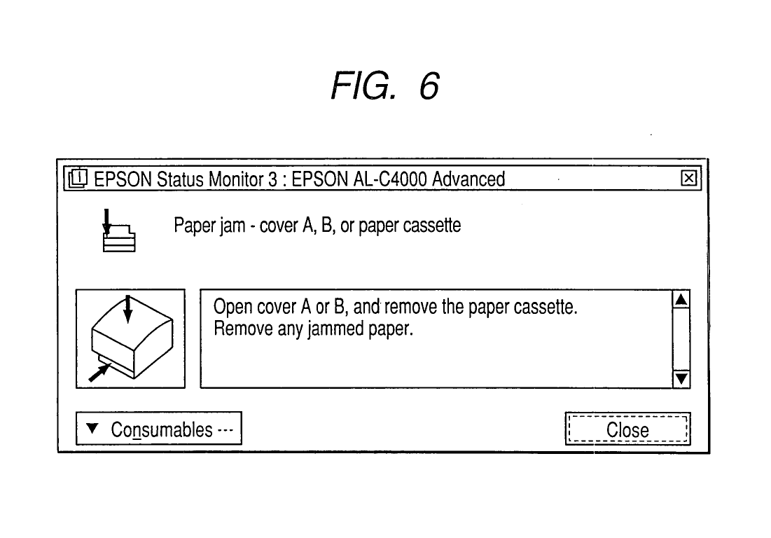

The operation of the computer 50 at the time of the paper jam occurrence notification processing will be discussed with FIGS. 3 and 4:

FIG. 3 is a flowchart of the paper jam occurrence notification processing and FIG. 4 is a drawing to show an example of the paper jam error notification window displayed by performing the paper jam occurrence notification processing. For convenience of the description to follow, the message associated with the nth bit (n=any of 1 to 3) in the paper jam definition information (see FIG. 2) is denoted as the nth bit relevant message, and the arrow image identified by the arrow image code associated with the nth bit is denoted as the nth bit relevant arrow image.

As shown in FIG. 3, the computer 50 starting the paper jam occurrence notification processing first sets (adds) paper jam relevant item information in (to) error notification window definition information, a copy of error notification window definition model information (step S101).

The error notification window definition information is information defining the structure (format) of an error notification window (in the paper jam occurrence notification processing, paper jam error notification window) displayed on the display at step S108. The error notification window definition model information is information for displaying an error notification window scarcely indicating significant information (blank in areas 11 to 13 in FIG. 4) if processing at step S108 is performed with the error notification window definition model information used intact as the error notification window definition information.

The paper jam relevant item is an item always displayed on the paper jam error notification window (regardless of where a jam occurs), and the paper jam relevant item information is information defining the contents of the paper jam relevant item (information to display the paper jam relevant item on the paper jam error notification window).

The printer utility program 10 is a program with an image representing a paper jam state and a message (character string) of “Paper Jam” indicated in the area 11 of the paper jam error notification window (FIG. 4), a message of “Follow the instructions below, then remove any jammed paper.” indicated in the area 13, and an appearance image of the printer 30 (with no arrow) indicated in the area 12 as the paper jam relevant items.

Upon completion of the processing at step S101, the computer 50 determines whether the first bit of the display description specification information is ON or OFF (“1” or “0”) (step S102). If the first bit is ON (ON at step S102), the computer 50 sets information for the first bit relevant message and information for the first bit relevant arrow image in the error notification window definition information (step S103). More particularly, at step S103, the computer 50 sets the information in the error notification window definition information so that the paper jam error notification window (FIG. 4) displayed at step S108 indicates the first bit relevant message (message associated with the first bit in the paper jam definition information) one stage below an already existing message (message set as message already to be displayed) in the area 13 and the first bit relevant arrow image (arrow image identified by the arrow image code associated with the first bit in the paper jam definition information) in the area 12 (on the appearance image of the printer 30).

In the embodiment, the arrow image identified by arrow image code 7 (see FIG. 2) points to the top face of the printer 30 in the appearance image (the printer 30 includes covers A, D, and B on the top face side). Thus, as step S103 is executed, a paper jam error notification window indicating a downward arrow image on the appearance image of the printer 30 in the area 12 is displayed at step S108.

Upon completion of the processing concerning the first bit (upon completion of the processing at step S103 or when the determination at step S102 is OFF), the computer 50 determines whether the second bit of the display description specification information is ON or OFF (step S104). If the second bit of the display description specification information is ON (ON at step S104), the computer 50 sets information for the second bit relevant message and information for the second bit relevant arrow image in the error notification window definition information (step S105). The processing at step S105 is the same as that at step S103 except that if the error notification window definition information is information to indicate the same arrow image as the second bit relevant arrow image in the area 12 (if the first and second bits of the display description specification information are both ON), the information for the second bit relevant arrow image is not set in the error notification window definition information.

Upon completion of the processing concerning the second bit (upon completion of the processing at step S105 or when the determination at step S104 is OFF), the computer 50 determines whether the third bit of the display description specification information is ON or OFF (step S106). If the third bit of the display description specification information is ON (ON at step S106), the computer 50 sets information for the third bit relevant message and information for the third bit relevant arrow image in the error notification window definition information (step S107). The processing at step S107 is the same as that at step S105.

In the embodiment, the arrow image identified by arrow image code 20 (see FIG. 2) represents an upward-right arrow (represents an arrow pointing to the part where a paper cassette is placed in the appearance image).

Upon completion of the processing concerning the third bit (upon completion of the processing at step S107 or when the determination at step S106 is OFF), the computer 50 displays an error notification window responsive to the error notification window definition information at the point in time (namely, paper jam error notification window) on the display (step S108) and then completes the error occurrence notification processing.

Upon completion of the error occurrence notification processing, the computer 50 enters a state in which it monitors the user pressing a Close button on the paper jam error notification window or conducting work in accordance with the message displayed in the area 13 in the paper jam error notification window (the printer 30 being restored to the normal state). If the user presses the Close button on the paper jam error notification window, the computer 50 erases the paper jam error notification window from the display and then continues to monitor the operation state of the printer 30. If the printer 30 is restored to the normal state with the paper jam error notification window displayed on the display, the computer 50 also erases the paper jam error notification window from the display and then continues to monitor the operation state of the printer 30.

As seen from the description given above, the printer utility program 10 installed in the computer 50 of the print system according to the embodiment is a program for displaying seven types of paper jam error notification windows with three types of messages combined. Therefore, the printer utility program 10 is a program with the amount of information to be provided smaller than that of the monitor program 110 for which seven pieces of information are provided to display the paper jam error notification window (a program of a smaller size than the monitor program 110).

<Modifications>

The printer utility program 10 can be modified in various manners. For example, the printer utility program 10 may be modified to a program which does not have the function of monitoring the operation state of the printer 30 (for example, acquires status information from the printer 30 only when the user gives a predetermined command). A printer for transmitting status information containing display description specification information in a different format from that described above (display description specification information with bit values not provided with one-to-one correspondence with messages) may be used as the printer 30. However, if the printer 30 is thus configured, processing in the printer utility program 10 becomes a little complicated and therefore it is desirable that the configuration of the embodiment should be adopted.

The printer utility program 10 may be a program for handling a copier as the printer 30 or may be a program for displaying a message concerning a handling method according to the above-described procedure in addition to the case where a paper jam occurs, of course.

Further, the printer utility program 10 is a program for displaying information having several messages in combination with the message display order fixed (the first bit relevant message is not displayed below the third bit relevant message) as information concerning the abnormal phenomenon handling method. However, a printer utility program for displaying information having messages in combination with the message display order unfixed as information concerning the abnormal phenomenon handling method may be created based on the technique used in the printer utility program 10. Such a printer utility program can also be created as the printer 30 is modified so as to transmit information specifying the display order or the program can also be created containing information as to the messages are to be displayed in what combination in what order when various abnormal phenomena occur.

1. A printer utility program for causing a computer to operate as an apparatus comprising:
information storage means storing different types of pieces of character string information; and
information display means for determining an abnormal phenomenon occurring in a printer and displaying information provided by combining as many different types of pieces of character string information as the number of pieces of character string information responsive to the determined abnormal phenomenon, stored in said information storage means as information concerning a handling method of the abnormal phenomenon occurring in the printer.

2. The printer utility program as claimed in claim 1,
wherein the printer is capable of transmitting display description specification information specifying one or more pieces of character string information stored in said information storage means to a different apparatus, and
wherein said information display means displays information provided by combining one or more pieces of character string information stored in said information storage means and specified by the display description specification information transmitted by the printer.

3. The printer utility program as claimed in claim 2,
wherein said information display means displays information provided by combining one or more pieces of character string information stored in said information storage means and specified by the display description specification information transmitted by the printer and displaying an image provided by combining one or more images provided in a one-to-one correspondence with the one or more pieces of character string information.

4. The printer utility program as claimed in claim 1,
wherein said apparatus further comprises monitor means for monitoring occurrence of an abnormal phenomenon in the printer,
wherein said information display means functions when the monitor means detects occurrence of an abnormal phenomenon.

5. The printer utility program as claimed in claim 2,
wherein said apparatus further comprises monitor means for monitoring occurrence of an abnormal phenomenon in the printer,
wherein said information display means functions when the monitor means detects occurrence of an abnormal phenomenon.

6. The printer utility program as claimed in claim 3,
wherein said apparatus further comprises monitor means for monitoring occurrence of an abnormal phenomenon in the printer,
wherein said information display means function s when the monitor means detects occurrence of an abnormal phenomenon.

7. A print system comprising:
a printer; and
a host device,
wherein said printer includes:
a state information transmission section for transmitting status information containing as many different types of pieces of character string specification information as the number of pieces of character string information responsive to the type of abnormal phenomenon occurring in said printer to a different apparatus, and
wherein said host device includes:
an information storage section for storing character string information for each piece of character string specification information contained in the status information transmitted by the state information transmission section of said printer; and
an information display section for displaying information provided by combining pieces of character string information stored in the information storage section about each piece of indication information contained in the status information transmitted by the state information transmission section of said printer as information concerning a handling method of the abnormal phenomenon occurring in the printer.

8. A printer monitoring method comprising the steps of:
determining an abnormal phenomenon occurred in a printer connected with said computer via a network;
identifying a type of the determined abnormal phenomenon;
preparing information indicating a handling method corresponding to the identified type of the abnormal phenomenon, by referring to character string information stored in a storage section of said computer; and
displaying the prepared information indicating a handling method.

9. The printer monitoring method as claimed in claim 8,
wherein said character string information corresponds to at least an image, and
wherein, in the step of displaying, one or more images corresponding to character string information to which referred in order to preparing the information indicating a handling method, said one or more images are displayed.
